(19) United States
(12) Patent Application Publication
(10) Pub. No.: US 2025/0147415 A1
(43) Pub. Date: May 8, 2025

(54) RESIST COMPOSITION AND METHOD OF FORMING PATTERNS USING THE SAME

(71) Applicant: Samsung Electronics Co., Ltd., Suwon-si (KR)

(72) Inventors: Sunyoung LEE, Suwon-si (KR); Haengdeog KOH, Suwon-si (KR); Yoonhyun KWAK, Suwon-si (KR); Jiyoun LEE, Suwon-si (KR); Kyuhyun IM, Suwon-si (KR); Jinwon JEON, Suwon-si (KR); Jungha CHAE, Suwon-si (KR); Minyoung HA, Suwon-si (KR)

(73) Assignee: Samsung Electronics Co., Ltd., Suwon-si (KR)

(21) Appl. No.: 18/635,761

(22) Filed: Apr. 15, 2024

(30) Foreign Application Priority Data
Nov. 6, 2023 (KR) 10-2023-0151944

(51) Int. Cl. G03F 7/004

(52) U.S. Cl. CPC G03F 7/0042

(57) ABSTRACT

Provided are a resist composition and a pattern formation method using the same. The resist composition may include an organometallic compound represented by one of Formulae 1-1 to 1-4, and an additive represented by Formula 2:

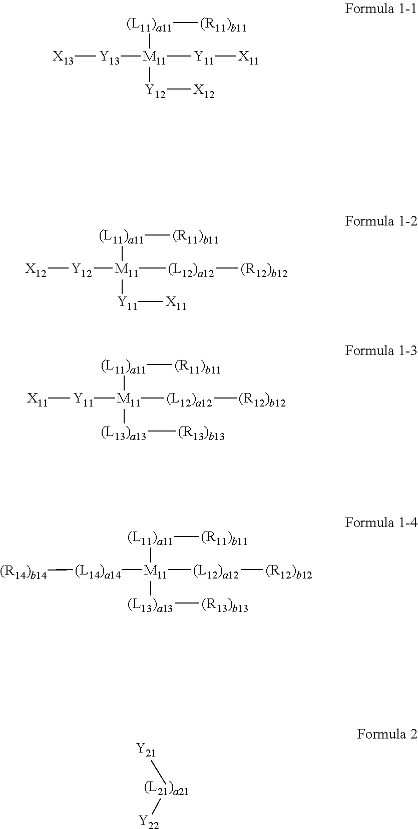

wherein M₁₁, L₁₁ to L₁₄, a11 to a14, R₁₁ to R₁₄, b11 to b14, Y₁₁ to Y₁₃, X₁₁ to X₁₃, Y₂₁, Y₂₂, L₂₁, and a21 in Formulae 1-1 to 1-4 and 2 are described in the specification.

### CROSS-REFERENCE TO RELATED APPLICATION

This application is based on and claims priority under 35 U.S.C. § 119 to Korean Patent Application No. 10-2023-0151944, filed on Nov. 6, 2023, in the Korean Intellectual Property Office, the disclosure of which is incorporated by reference herein in its entirety.

### BACKGROUND

### 1. Field

The disclosure relates to a resist composition and a pattern formation method using the same.

### 2. Description of the Related Art

During manufacturing of semiconductors, resists, of which physical properties change in response to light, are being used to form fine patterns. Among the resists, chemically amplified resists have been widely used. In the case of chemically amplified resists, an acid formed through a reaction between light and a photoacid generator reacts with a base resin again to change the solubility of the base resin with respect to a developer, thereby enabling patterning.

However, in the case of chemically amplified resists, the diffusion of the acid formed into non-exposed areas can lead to poor pattern uniformity and increased surface roughness. With increasingly miniaturized semiconductor processes, it is not easy to control the diffusion of acids, resulting in the need to develop a new type of resist.

Recently, in order to overcome the limits of chemically amplified resists, attempts have been made to develop materials of which physical properties change due to exposure to light. However, the high dose required for exposure is still high.

### SUMMARY

Provided is a resist composition having improved storage stability, whose properties change even with low doses of exposure, and which provides patterns of improved resolution, and a pattern formation method using the same.

Additional aspects will be set forth in part in the description which follows and, in part, will be apparent from the description, or may be learned by practice of the presented embodiments of the disclosure.

According to an example embodiment, a resist composition may include an organometallic compound represented by one of Formulae 1-1 to 1-4, and an additive represented by Formula 2.

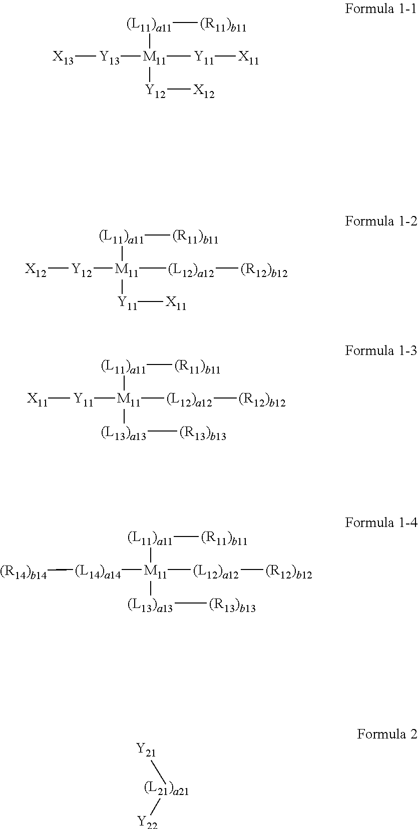

In Formulae 1-1 to 1-4 and 2,
M₁₁ may be indium (In), tin (Sn), antimony (Sb), tellurium (Te), thallium (Tl), lead (Pb), bismuth (Bi), or polonium (Po),
L₁₁ to L₁₄ may each independently be a single bond or a linear, branched, or cyclic C₁-C₃₀ divalent hydrocarbon group,
a11 to a14 may each independently be an integer from 1 to 4, and
R₁₁ to R₁₄ may each independently be a substituted or unsubstituted C₃-C₃₀ branched alkyl group, a substituted or unsubstituted C₃-C₃₀ cycloalkyl group, a substituted or unsubstituted C₃-C₃₀ heterocycloalkyl group, a or a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
an adjacent two of R₁₁ to R₁₄ may be optionally combined with each other to form a condensed ring,
b11 to b14 may each independently be an integer from 1 to 4,
Y₁₁ to Y₁₃ may each independently be O, O(C═O), S, S(C═O), NX₁₄, or N(C═O), and
X₁₁ to X₁₄ may each independently be hydrogen, deuterium, or a linear, branched, or cyclic C₁-C₃₀ monovalent hydrocarbon group optionally including a heteroatom,
Y₂₁ and Y₂₂ may each independently be a linear, branched, or cyclic C₁-C₃₀ monovalent hydrocarbon group containing, as a heteroatom, at least one selected from an oxygen atom, a sulfur atom, a nitrogen atom and a phosphorus atom,
L₂₁ may be a single bond, a double bond, or a linear, branched, or cyclic C₁-C₃₀ divalent hydrocarbon group,
a21 may be an integer from 1 to 4, and
an adjacent two of Y₂₁, Y₂₂, and L₂₁ may be optionally combined with each other to form a condensed ring.

According to an example embodiment, a pattern formation method may include forming a resist film by applying the resist composition on a substrate, exposing at least a portion of the resist film with high energy rays to provide an exposed resist film, and developing the exposed resist film using a developer.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a pattern formation method according to an embodiment;

FIGS. 2A to 2C are side cross-sectional views illustrating a pattern formation method according to an embodiment;

FIG. 3A is a diagram showing the change in film thickness after development depending on the dose of Comparative Example 3-1; and

FIG. 3B is a diagram showing the change in film thickness after development depending on the dose of Example 3-1.

FIGS. 4A to 4E are side cross-sectional views illustrating a method of forming a patterned structure according to an embodiment; and

FIGS. 5A to 5E are side cross-sectional views illustrating a method of forming a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”, “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Since the disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cₓ-C_{y}” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound containing carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e. g., a phenyl group, a 1-naphthyl group, and a 2-naphthyl group); an arylalkyl group (e. g., a benzyl group and a diphenylmethyl group); a heteroatom-containing monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. In some embodiments, some of hydrogens in these groups may be substituted by a moiety including a heteroatom such as oxygen, sulfur, nitrogen, phosphorus or halogen atoms, or some of carbons in these groups may be replaced by a moiety including a heteroatom such as oxygen, sulfur, nitrogen, or phosphorus. Accordingly, these groups may include a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, etc.

The term “divalent hydrocarbon group” as used herein is a divalent residue and means that any one hydrogen atom of the monovalent hydrocarbon group is replaced with a bonding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and non-limiting examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and non-limiting examples thereof may include a methylene group, an ethylene group, a propylene group, a butylene group, and an isobutylene group.

The term “halogenated alkyl group” as used herein refers to a group in which at least one substituent of an alkyl group is substituted with a halogen atom, and examples thereof may include CF₃. In this regard, the halogen atom is F, Cl, Br, or I.

The term “alkoxy group” as used herein refers to a monovalent group having a formula of -OA₁₀₁, wherein A₁₀₁ is an alkyl group. Specific examples thereof include a methoxy group, an ethoxy group, an isopropyloxy group, and the like.

The term “alkylthio group” as used herein refers to a monovalent group having a formula of -SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof include —OCF₃ and the like.

The term “halogenated alkylthio group” as used herein refers to a group in which one or more hydrogen atoms of an alkylthio group are substituted with a halogen atom, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group having a formula of -OA₁₀₂, wherein A₁₀₂ is a cycloalkyl group. Specific examples thereof include a cyclopropoxy group, a cyclobutoxy group, and the like.

The term “cycloalkylthio group” as used herein refers to a monovalent group having a formula of -SA₁₀₂, wherein A₁₀₂ is a cycloalkyl group.

The term “heterocycloalkyl group” as used herein may be a group in which some carbon atoms of the cycloalkyl group are replaced by a moiety including a heteroatom, for example, oxygen, sulfur, or nitrogen. The heterocycloalkyl group may include an ether bond, an ester bond, a sulfonate ester bond, carbonate, a lactone ring, a sultone ring, or a carboxylic anhydride moiety. The term “heterocycloalkylene group” as used herein refers to a group in which some carbon atoms of the cycloalkylene group are replaced by a moiety including a heteroatom, for example, oxygen, sulfur, or nitrogen.

The term “heterocycloalkoxy group” as used herein refers to a monovalent group having a formula of -OA₁₀₃, wherein A₁₀₃ is a heterocycloalkyl group.

The term “heterocycloalkylthio group” as used herein refers to a monovalent group having the formula of -SA₁₀₃ wherein A₁₀₃ may be a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

The term “heterocycloalkenyl group” as used herein refers to a group in which some carbon atoms of the cycloalkenylene group are replaced by a moiety including a heteroatom, for example, oxygen, sulfur, or nitrogen. The term “heterocycloalkenylene group” as used herein refers to a group in which some carbon atoms of the cycloalkenylene group are replaced by a moiety including a heteroatom, for example, oxygen, sulfur, or nitrogen.

The term “alkynyl group” as used herein refers to a linear or branched unsaturated aliphatic hydrocarbon monovalent group including one or more carbon-carbon triple bonds.

The term “aryl group” as used herein refers to a monovalent group having a carbocyclic aromatic system, and non-limiting examples thereof may include a phenyl group, a naphthyl group, anthracenyl group, a phenanthrenyl group, a pyrenyl group, and a chrysenyl group. The term “arylene group” as used herein refers to a divalent group having a carbocyclic aromatic system.

The term “aryloxy group” as used herein refers to a monovalent group represented by -OA₁₀₄, wherein A₁₀₄ is an alkyl group.

The term “arylthio group” as used herein refers to a monovalent group represented by -SA₁₀₄, wherein A₁₀₄ is an alkyl group.

The term “heteroaryl group” as used herein refers to a monovalent group having a heterocyclic aromatic system, and specific examples thereof include a pyridinyl group, a pyrimidinyl group, a pyrazinyl group, and the like. The term “heteroarylene group” as used herein refers to a divalent group having a heterocyclic aromatic system.

The term “heteroaryloxy group” as used herein refers to a monovalent group represented by -OA₁₀₅, wherein A₁₀₅ is a heteroaryl group.

The term “heteroarylthio group” as used herein refers to a monovalent group represented by -SA₁₀₅, wherein A₁₀₅ is a heteroaryl group.

The term “arylalkyl group” as used herein refers to a group in which an alkyl group is substituted with a monovalent group having a carbocyclic aromatic system, and specific examples include a benzyl group, a diphenylmethyl group, etc.

The term “heteroarylalkyl group” as used herein refers to a group in which an alkyl group is substituted with a monovalent group having a heterocyclic aromatic system.

The term “heterocyclic group” as used herein refers to a monocyclic or polycyclic group having 1 to 60 carbon atoms including at least one heteroatom, and is a group that includes a monovalent group, a divalent group, and a trivalent group.

The term “substituent” as used herein includes deuterium, a halogen atom, a cyano group, a nitro group, a hydroxy group, a thiol group, an amino group, a carboxylate group, an ether moiety, a thioether moiety, a carbonyl moiety, an ester moiety, a phosphonate. moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or a combination thereof; and a combination thereof.

Hereinafter, embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Resist Composition]

Resist compositions according to embodiments include an organometallic compound represented by one of Formulae 1-1 to 1-4 and an additive represented by Formula 2:

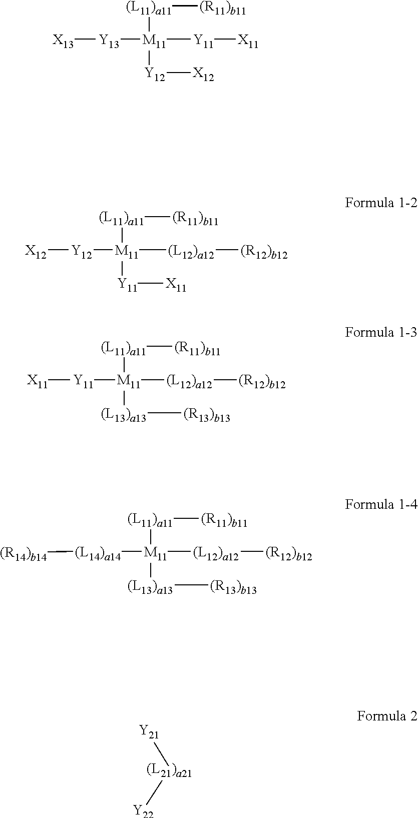

wherein, in Formulae 1-1 to 1-4 and 2,
M₁₁ may be indium (In), tin (Sn), antimony (Sb), tellurium (Te), thallium (Tl), lead (Pb), bismuth (Bi), or polonium (Po),
L₁₁ to L₁₄ may each independently be a single bond or a linear, branched, or cyclic C₁-C₃₀ divalent hydrocarbon group,
a11 to a14 are each independently an integer from 1 to 4, and
R₁₁ to R₁₄ may each independently be a substituted or unsubstituted C₃-C₃₀ branched alkyl group, a substituted or unsubstituted C₃-C₃₀ cycloalkyl group, a substituted or unsubstituted C₃-C₃₀ heterocycloalkyl group, a or a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
an adjacent two of R₁₁ to R₁₄ may be optionally combined with each other to form a condensed ring,
b11 to b14 may each independently be an integer from 1 to 4,
Y₁₁ to Y₁₃ may each independently be O, O(C═O), S, S(C═O), NX₁₄, or N(C═O), and
X₁₁ to X₁₄ may each independently be hydrogen, deuterium, or a linear, branched, or cyclic C₁-C₃₀ monovalent hydrocarbon group optionally including a heteroatom,
Y₂₁ and Y₂₂ may each independently be a linear, branched, or cyclic C₁-C₃₀ monovalent hydrocarbon group containing, as a heteroatom, at least one selected from an oxygen atom, a sulfur atom, a nitrogen atom and a phosphorus atom,
L₂₁ may be a single bond, a double bond, or a linear, branched, or cyclic C₁-C₃₀ divalent hydrocarbon group,
a21 may be an integer from 1 to 4, and
an adjacent two of Y₂₁, Y₂₂, and L₂₁ may be optionally combined with each other to form a condensed ring,

The molecular weight of the organometallic compound may be 3000 g/mol or less. In an embodiment, the molecular weight of the organometallic compound may be 2000 g/mol or less.

Although not limited to any particular theory, the organometallic compound may be capable of forming radicals by heat and/or high-energy radiation. In an embodiment, a radical may be formed from the Mu-carbon bond of the organometallic compound, and optionally in an atmosphere where water is present, the radical may react to form a chemical bond between organometallic compounds. Accordingly, the physical properties of the organometallic compound, for example, the solubility thereof with respect to a developer, may change.

The organometallic compound represented by one of Formulae 1-1 to 1-4 necessarily include at least one of R₁₁ to R₁₄ which have relatively low C—H bond decomposition energy. Accordingly, the photosensitivity thereof with respect to high-energy rays, for example, extreme ultraviolet (EUV) rays may be improved. Specifically, R₁₁ to R₁₄ in the organometallic compound represented by one of Formulae 1-1 to 1-4 cannot be a linear alkyl group. In the case of a linear alkyl group, a radical formed by balanced hemolysis of the CH bond is relatively unstable and thus, the C—H bond decomposition energy is relatively high. Accordingly, the linear alkyl group is not appropriate for R₁₁ to R₁₄.

For example, M₁₁ in Formulae 1-1 to 1-4 may be In, Sn, or Sb. In an embodiment, Mu in Formulae 1-1 to 1-4 may be Sn.

In some embodiments, L₁₁ to L₁₄ in Formulae 1-1 to 1-4 may each independently be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

In some embodiments, L₁₁ to L₁₄ in Formulae 1-1 to 1-4 may each independently be: a single bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In some embodiments, L₁₁ to L₁₄ in Formulae 1-1 to 1-4 may each independently be: a single bond; and a C₁-C₃₀ alkylene group that is unsubstituted or substituted with deuterium, a halogen atom, a hydroxyl group, a cyano group, a C₁-C₂₀ alkyl group, a C₁-C₂₀ halogenated alkyl group, or a combination thereof.

For example, a11 to a14 in Formulae 1-1 to 1-4 may each independently be an integer of 1 or 2.

In some embodiments, R₁₁ to R₁₄ in Formulae 1-1 to 1-4 may each independently be selected from: a branched C₃-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In some embodiments, R₁₁ to R₁₄ in Formulae 1-1 to 1-4 may each independently be selected from a branched C₃-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ alkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In some embodiments, R₁₁ to R₁₄ in Formulae 1-1 to 1-4 may each independently be one of Formulae 3-1 to 3-15:

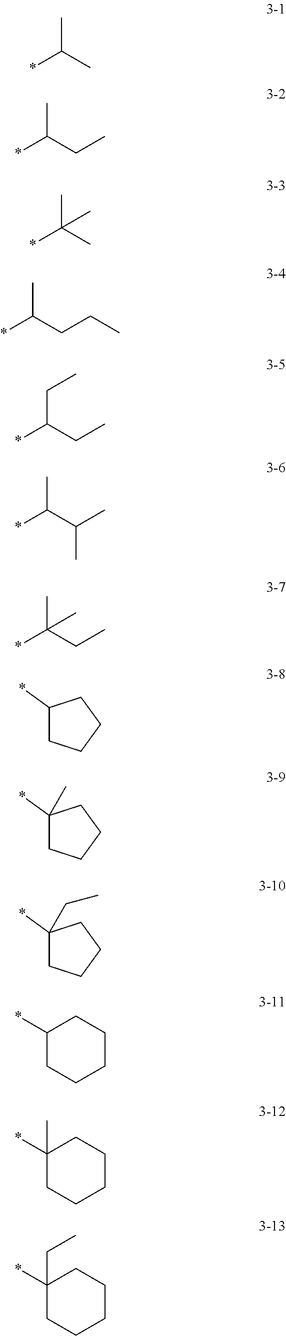

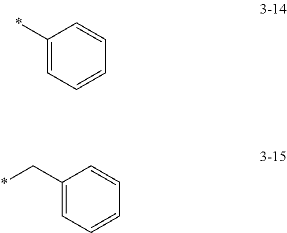

wherein, in Formulae 3-1 to 3-15,
at least one hydrogen may be optionally substituted with deuterium, a halogen atom, a cyano group, a nitro group, a hydroxy group, a thiol group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, or a combination thereof.
b11 to b14 in Formulae 1-1 to 1-4 refer to the number of substituent R₁₁ to the number of substituent R₁₄, respectively. For example, b11 to b14 in the Formulae 1-1 to 1-4 may each independently be 1 or 2.

An adjacent two of R₁₁ to R₁₄ may be optionally combined with each other to form a condensed ring.

For example, an adjacent two of a plurality of R₁₁ may be selectively combined with each other to form a condensed ring, an adjacent two of a plurality of R₁₂ may be selectively combined with each other to form a condensed ring, and an adjacent two of a plurality of R₁₃ may be selectively combined with each other to form a condensed ring, and an adjacent two of a plurality of R₁₄ may be selectively combined with each other to form a condensed ring.

In some embodiments, an adjacent two of R₁₁ to R₁₄ may be optionally combined with each other to form a condensed ring.

For example, Y₁₁ to Y₁₃ in Formulae 1-1 to 1-4 may each independently be O, O(C═O), S, or S(C═O).

For example, X₁₁ to X₁₄ in Formulae 1-1 to 1-4 may each independently be selected from: hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof, a substituted or unsubstituted.

In some embodiments, X₁₁ to X₁₄ in Formulae 1-1 to 1-4 may each independently be selected from: hydrogen; deuterium; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or a combination thereof.

In some embodiments, X₁₁ to X₁₄ in Formulae 1-1 to 1-4 may each independently selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, and a C₆-C₃₀ aryl group, each unsubstituted or substituted with deuterium, a halogen atom, or a combination thereof.

In some embodiments, X₁₁ to X₁₄ in Formulae 1-1 to 1-4 may each independently be: hydrogen; deuterium; and a methyl group, an ethyl group, an n-propyl group, an iso-propyl group, an n-butyl group, a sec-butyl group, an iso-a butyl group, a tert-butyl group, a cyclopentyl group, a cyclohexyl group, an ethenyl group, a cyclopentenyl group, a cyclopentadienyl group, a cyclohexenyl group, a cyclohexadienyl group, an ethynyl group, a phenyl group, and a naphthyl group, each unsubstituted or substituted with deuterium, a halogen atom, a methyl group, an ethyl group, a phenyl group, a naphthyl group, or a combination thereof.

In an embodiment, the organometallic compound represented by one of Formulae 1-1 to 1-4 may be selected from Group I:

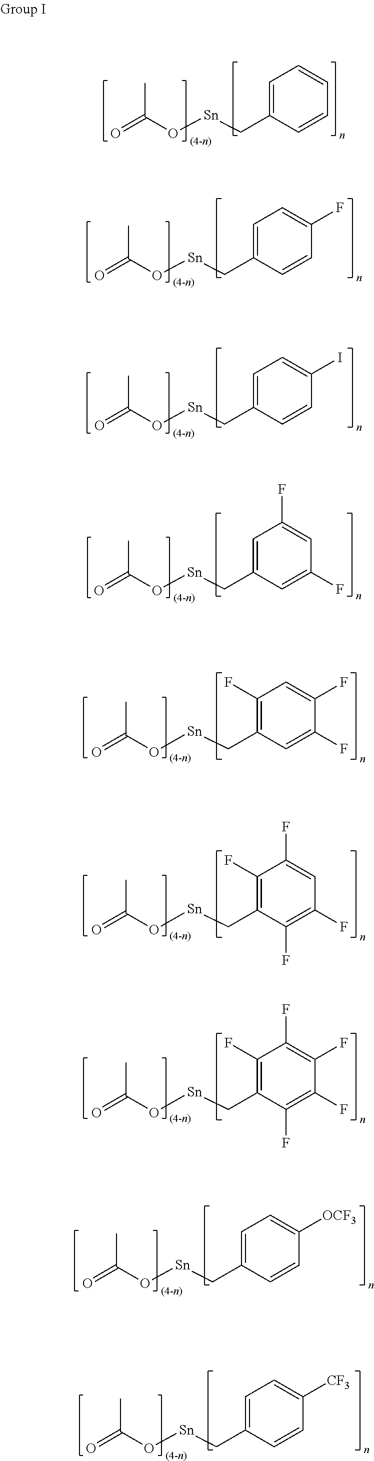

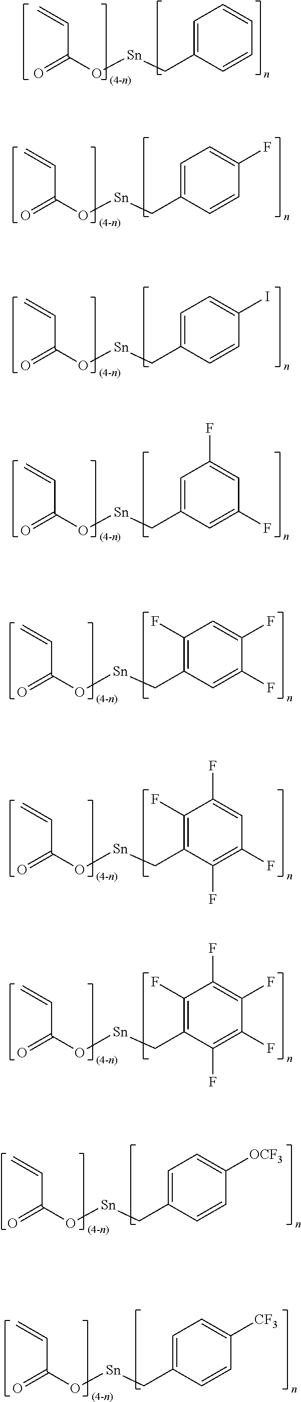

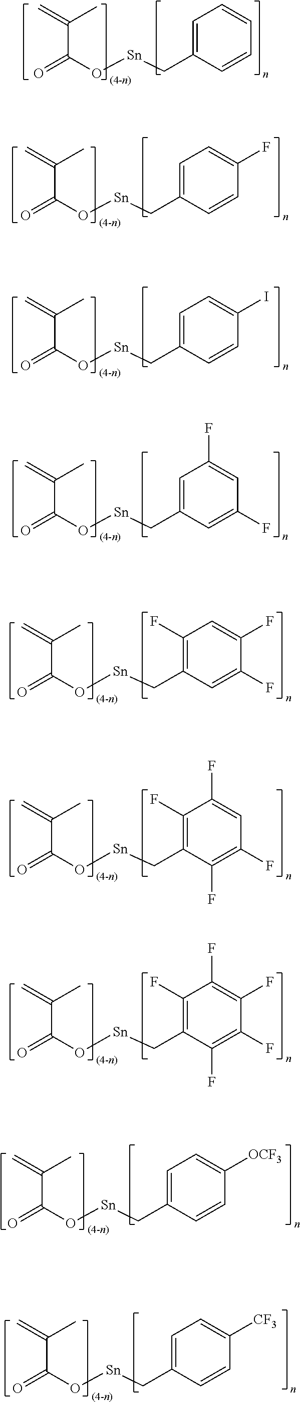

wherein n in Group I is an integer from 1 to 4.

For example, n in Group I may be 2.

For example, Y₂₁ in Formula 2 may be represented by one of Formulae 4-1 to 4-5, and Y₂₂ may be represented by one of Formulae 4-6 to 4-10:

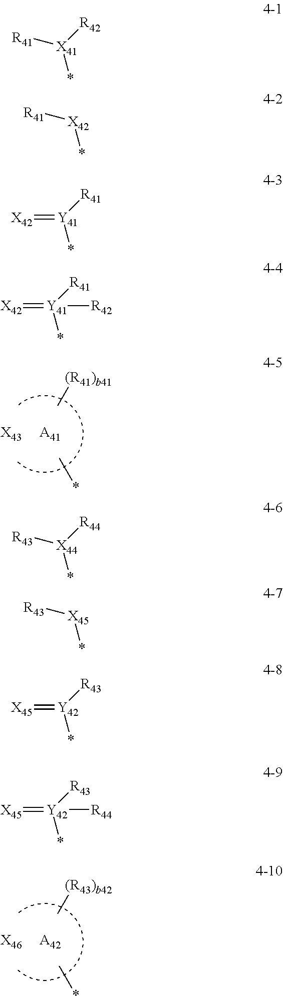

wherein, in Formulae 4-1 to 4-10,
X₄₁ and X₄₄ may each independently be N or P,
X₄₂ and X₄₅ may each independently be O or S,
X₄₃ and X₄₆ may each independently be O, S, N, or P,
Y₄₁ and Y₄₂ may each independently be C, S, or P,
A₄₁ may be a C₁-C₃₀ heterocyclic group including X₄₃ as a ring member,
A₄₂ may be a C₁-C₃₀ heterocyclic group including X₄₆ as a ring member,
R₄₁ to R₄₄ may each independently be hydrogen, deuterium, a halogen atom, a cyano group, a nitro group, a hydroxy group, a thiol group, an amino group, a carboxylate group, or a linear, branched, or cyclic C₁-C₃₀ divalent hydrocarbon group,
b41 and b42 may each independently be an integer from 1 to 10, and
* indicates a binding site to a neighboring atom.

In an embodiment, the additive has a structure in which one of X₄₁ to X₄₃ and one of X₄₄ to X₄₆ are coordinated to a metal atom, for example, Mn, to form a five-membered, six-membered, or seven-membered ring.

For example, A₄₁ and A₄₂ in Formulae 4-5 and 4-10 may each independently be i) a monovalent group derived from a first ring, ii) a monovalent group derived from a condensed ring in which two or more first rings are condensed with each other, or iii) a monovalent group derived from a condensed ring in which one or more first rings are condensed with one or more second rings,
the first ring may be tetrahydropyran, dihydropyran, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine, or triazine, and
the second ring may be cyclopentane, cyclopentadiene, cyclohexane, cyclohexene, cyclohexadiene, benzene, or naphthalene.

For example, A₄₁ and A₄₂ in Formulae 4-5 and 4-10 may each independently be i) a monovalent group derived from a first ring, ii) a monovalent group derived from a condensed ring in which two or more first rings are condensed with each other, or iii) a monovalent group derived from a condensed ring in which one or more first rings are condensed with one or more second rings,
the first ring may be tetrahydropyran, dihydropyran, pyran, tetrahydrothiopyran, dihydrothiopyran, thiopyran, tetrahydrofuran, dihydrofuran, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine, or triazine, and
the second ring may be benzene.

For example, R₄₁ to R₄₄ in Formula 4-1 to 4-10 may each independently be selected from: hydrogen; deuterium; a halogen atom; a cyano group; a nitro group; a hydroxyl group; a thiol group; an amino group; a carboxylate group; and a C₁-C₃₀ alkyl group, a C₁-C₃₀ halogenated alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ alkyl group, a C₁-C₃₀ heteroaryl group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ Heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In some embodiments, R₄₁ to R₄₄ in Formula 4-1 to 4-10 may each independently be selected from: hydrogen; deuterium; a halogen atom; a cyano group; a nitro group; a hydroxyl group; a thiol group; an amino group; a carboxylate group; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or a combination thereof.

In an embodiment, in Formula 2, i) Y₂₁ is represented by Formula 4-5, and Y₂₂ is represented by one of Formulae 4-6 to 4-10, or
ii) Y₂₁ may be represented by one of Formulae 4-1 to 4-5, and Y₂₂ may be represented by Formula 4-10.

In an embodiment, in Formula 2, Y₂₁ may be represented by Formula 4-5, and Y₂₂ may be represented by Formula 4-10.

In some embodiments, L₂₁ in Formula 2 may be a single bond, a double bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

In some embodiments, L₂₁ in Formula 2 may be selected from: a single bond; a double bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety., a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In some embodiments, L₂₁ in Formula 2 may be selected from: a single bond; a double bond; and a C₁-C₃₀ alkylene group and a C₂-C₃₀ alkenylene group, each unsubstituted or substituted with deuterium, a halogen atom, a hydroxyl group, a cyano group, a C₁-C₂₀ alkyl group, a C₁-C₂₀ halogenated alkyl group, or a combination thereof.

In an embodiment, the additive may be represented by Formula 2-1:

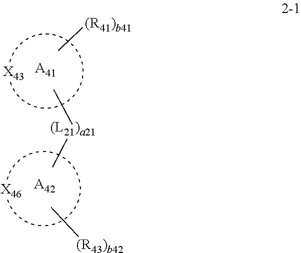

wherein in Formula 2-1,
X₄₃, X₄₆, A₄₁, A₄₂, L₂₁, a21, R₄₁ to R₄₄, b41, and b42 may be the same as described above.

In an embodiment, the additive may be represented by Formula 2-11 or Formula 2-12:

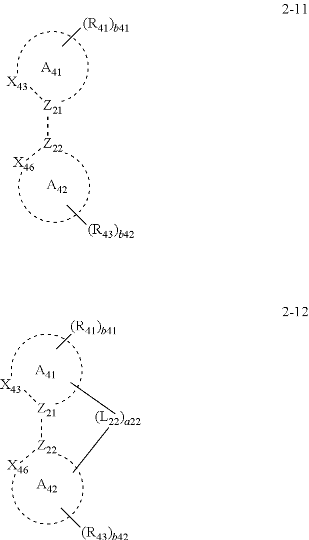

wherein, in Formulae 2-11 and 2-12,
X₄₃ and X₄₆ may each independently be O, S, N, or P,
A₄₁ may be a C₁-C₃₀ heterocyclic group including X₄₃ as a ring member,
A₄₂ may be a C₁-C₃₀ heterocyclic group including X₄₆ as a ring member,
Z₂₁ and Z₂₂ may each independently be C or N,
a bond between Z₂₁ and Z₂₂ may be a single bond or a double bond,
L₂₂ may be a single bond; a double bond; and a C₁-C₃₀ alkylene group and a C₂-C₃₀ alkenylene group, each unsubstituted or substituted with deuterium, a halogen atom, a hydroxyl group, a cyano group, a C₁-C₂₀ alkyl group, a C₁-C₂₀ halogenated alkyl group, or a combination thereof,
a22 may be an integer from 1 to 4,
R₄₁ to R₄₄ may each independently be a linear, branched, or cyclic C₁-C₃₀ divalent hydrocarbon group, and
b41 and b42 may each independently an integer from 1 to 10.

In Formulae 2-11 and 2-12, the bond between X₄₃ and Z₂₁ and the bond between Z₂₂ and X₄₆ may each independently be a single bond or a double bond.

For example, in Formulae 2-11 and 2-12, there may be three chemical bonds between X₄₃ and X₄₆, and the three chemical bonds may include the chemical bond between X₄₃ and Z₂₁, the chemical bond between Z₂₁ and Z₂₂, and the chemical bond between Z₂₂ and X₄₆.

In an embodiment, the additive may be selected from Group II:

### Group II

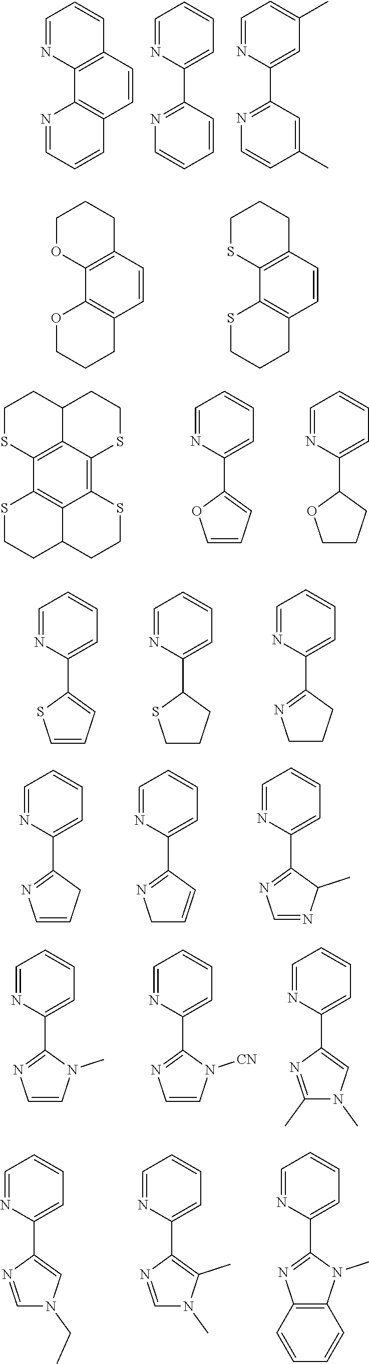

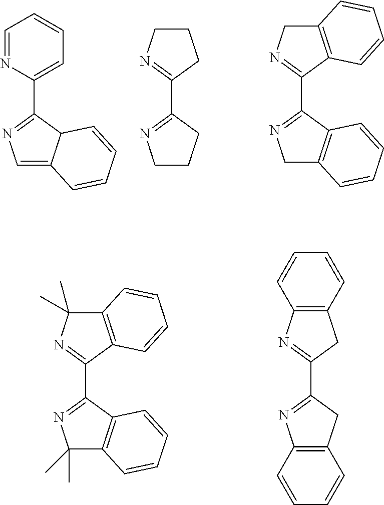

Since the additive contains N, O, S and/or P that provide lone-pair electrons, it can provide a coordination bond to the organometallic compound, thereby improving the chemical stability of the organometallic compound.

The organometallic compound may be one type of Formulae 1-1 to 1-4, or a mixture of two or more types thereof.

Likewise, the additive may be one type represented by Formula 2, or a mixture of two or more types thereof.

The amount of the organometallic compound in the resist composition may be, based on 100 parts by weight of the resist composition, from about 0.01 parts by weight to about 100 parts by weight, for example, 0.2 parts by weight or more, 0.5 parts by weight or more, 1 part by weight or more, or 1.5 parts by weight or more, and 90 parts by weight or less, or 80 parts by weight or less. Within these ranges, chemical bonds between organometallic compounds are sufficiently formed while side reactions are suppressed, thereby providing a resist composition with improved sensitivity and/or resolution.

The amount of the additive in the resist composition may be, based on 100 parts by weight of the resist composition, from about 0.01 parts by weight to about 100 parts by weight, for example, 0.2 parts by weight or more, 0.5 parts by weight or more, 1 part by weight or more, or 1.5 parts by weight or more, and 90 parts by weight or less, or 80 parts by weight or less. Within these ranges, chemical bonds between organometallic compounds are sufficiently formed while side reactions are suppressed, thereby providing a resist composition with improved sensitivity and/or resolution.

The amount of the additive in the resist composition may be from about 0.1 parts by weight to about 100,000 parts by weight based on 100 parts by weight of the organometallic compound. In some embodiments, the additive may be included in an amount of about 10 parts by weight to about 1,000 parts by weight, based on 100 parts by weight of the organometallic compound. Within these ranges, storage stability can be significantly improved while the photoresponsiveness of the resist composition is maintained at the resist composition level of a resist composition to which an additive is added.

The solubility of the resist composition in a developer may be changed by exposure to high energy rays. The resist composition may be a negative resist composition in which an unexposed portion of the resist film is dissolved and removed to form a negative resist pattern, or a positive resist composition in which an exposed portion is dissolved and removed to form a positive resist pattern. The resist composition may be modified in various ways. For example, the resist composition may be of a negative type or a positive type, depending on the exposure intensity and/or the type of developer.

In addition, the resist composition according to an embodiment may be: for an alkaline developing process using an alkaline developer for developing treatment when forming a resist pattern; or for a solvent developing process using a developer containing an organic solvent for the developing treatment (hereinafter, also referred to as an organic developer).

The resist composition may be non-chemically amplified. In this case, a photoacid generator substantially may not included.

Since the physical properties of the organometallic compound change by exposure, the resist composition may not substantially include compounds with a molecular weight of 1,000 or more other than the organometallic compound.

The organometallic compound and the additive may be manufactured by any suitable method, or commercially available products may be used therefor.

The structure (composition) of the organometallic compound may be identified through FT-IR analysis, NMR analysis, X-ray fluorescence (XRF) analysis, mass spectrometry, ultra violate (UV) analysis, single crystal X-ray structure analysis, powder X-ray diffraction (PXRD) analysis, liquid chromatography (LC), size exclusion chromatography (SEC) analysis, thermal analysis, etc. A detailed confirmation method is as described in Examples below.

### <Organic Solvent>

The resist composition may further include an organic solvent.

The organic solvent included in the resist composition is not particularly limited, as long as the organometallic compound, the additive, and any component contained therein as needed are dissolved or dispersed therein. As the organic solvent, one type of an organic solvent may be used, or two or more different types of organic solvents may be used in combination.

In an embodiment, the organic solvent may include a protic organic solvent, an aprotic organic solvent or a combination thereof.

In some embodiments, the organic solvent may be a mixture including an aprotic organic solvent and a protic organic solvent.

Since the resist composition may include substantially no water, the organic solvent may not include water. In an embodiment, the resist composition may include not more than 3 wt % water, and the organic solvent may include not more than 3 wt % water.

Examples of the organic solvent are an alcohol-based solvent, an ether-based solvent, a ketone-based solvent, an amide-based solvent, an ester-based solvent, a sulfoxide-based solvent, a hydrocarbon-based solvent, and the like.

Examples of the alcohol-based solvent may include: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexane alcohol, 3,3,5-trimethylcyclohexanol, benzyl alcohol, diacetone alcohol, and the like; a polyhydric alcohol solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-containing ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and the like.

Examples of the ether-based solvent may include: a dialkylether-based solvent, such as diethylether, dipropylether, dibutylether, diethylene glycol dimethylether, dipropyleneglycol dimethylether, and the like; a cyclic ether-based solvent, such as tetrahydrofuran, tetrahydropyran, and the like; and an aromatic ring-containing ether-based solvent, such as diphenylether, anisole, and the like.

Examples of the ketone-based solvent are a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone, a cyclic ketone-based solvent such as cyclopentanone, cyclohexanone, cycloheptanone, cyclooctanone, or methylcyclohexanone, 2,4-pentanedione, acetonyl acetone, and acetophenone.

Examples of the amide-based solvent are a cyclic amide-based solvent such as N,N′-dimethylimidazolidinone or N-methyl-2-pyrrolidone, and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent are: an acetate ester-based solvent, such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyhydric alcohol-containing ether carboxylate-based solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA) propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; a lactone solvent, such as γ-butyrolactone and δ-valerolactone; a carbonate-based solvent, such as dimethyl carbonate, diethyl carbonate, ethylene carbonate, and propylene carbonate; and a lactate ester-based solvent, such as methyl lactate, ethyl lactate, n-butyl lactate, and n-amyl lactate; glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvent are dimethyl sulfoxide and diethyl sulfoxide.

Examples of the hydrocarbon-based solvent are an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane, and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

In some embodiments, the organic solvent may be selected from alcohol-based solvents, ketone-based solvents, ester-based solvents, and any combinations thereof. In some embodiments, the organic solvent may be selected from 4-methyl-2-pentaneol (MIBC), propylene glycol monomethyl ether, propylene glycol monoethyl ether, propylene glycol monomethyl ether acetate, ethyl lactate, cyclohexanone, and a combination thereof.

The organic solvent may be used in an amount of about 0 parts by weight to about 99.9 parts by weight based on 100 parts by weight of the resist composition. The organic solvent may be used alone or any mixture of two or more different surfactants may also be used.

### <Any Components>

The resist composition may further include a surfactant, a crosslinking agent, a leveling agent, a colorant, or a combination thereof as necessary.

The resist composition may further include a surfactant to improve coatability, developability, and the like. Example of the surfactant are a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant are KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-11, Surflon™ SC-102, Surflon™ SC-103, Surflon™ SC-104, Surflon™ SC-105, and Surflon™ SC-106 (manufactured by AGC Seimi Chemical Co., Ltd.).

The surfactant may be included in a range of about 0 parts by weight to about 20 parts by weight based on 100 parts by weight of the resist composition. As the surfactant, one type of a surfactant may be used, or two or more different types of surfactants may be mixed and used.

A method of preparing the resist composition is not particularly limited, and the resist composition may be prepared by, for example, mixing the organometallic compound and optional components added as needed. A temperature or time during mixing is not particularly limited. If necessary, filtration may be performed after mixing.

### [Pattern Formation Method]

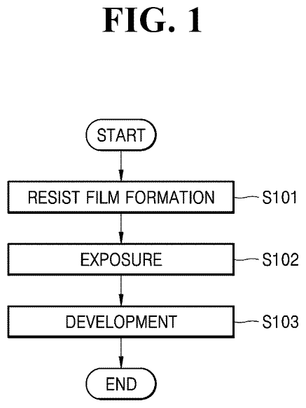

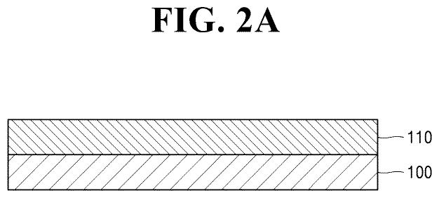

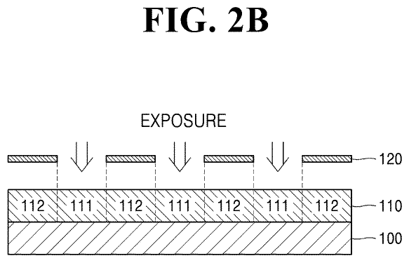

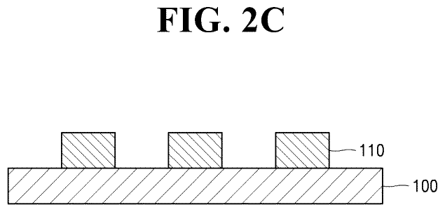

Hereinafter, a pattern formation method according to embodiments will be described in more detail with reference to FIGS. 1 and 2A to 2C. FIG. 1 is a flowchart representing a pattern formation method according to an embodiment, and FIGS. 2A to 2C are each a side cross-sectional view illustrating a pattern formation method according to an embodiment. Hereinafter, a pattern formation method using a negative resist composition will be described by way of example, but the embodiment is not limited thereto.

Referring to FIG. 1, the pattern formation method may include operation S101 of applying a resist composition to form a resist film, operation S102 of exposing at least a portion of the resist film to high energy rays to provide an exposed resist film, and operation S103 of developing the exposed resist film using a developer. Such operations may be omitted if necessary, or may be performed in a different order.

First, a substrate 100 may be prepared. The substrate 100 may include, for example, a semiconductor substrate such as a silicon substrate or a germanium substrate, glass, quartz, ceramic, or copper. In some embodiments, the substrate 100 may include a Group III-Group V compound such as GaP, GaAs, GaSb, or the like.

A resist composition may be applied to a desired thickness on the substrate 100 by, for example, coating, to form a resist film 110. If necessary, the resist film 110 may be heated (pre-baked, PB) to remove the organic solvent remaining therein. In some embodiments, by heating the resist film 110, radicals may be generated, and then through exposure, the radicals may chemically combine to form a crosslink.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. In some embodiments, the resist film 110 may have a thickness of about 10 nm to about 300 nm. In some embodiments, the resist film 110 may have a thickness of about 30 nm to about 200 nm.

The lower limit of the temperature of PB may be 60° C. or more or 80° C. or more. In some embodiments, the upper limit of the temperature of PB may be 150° C. or less, or 140° C. or less. The lower limit of the time of PB may be 5 seconds or more, or 10 seconds or more. The upper limit of the time of the PB may be 600 seconds or less or 300 seconds or less.

Before the applying of the resist composition on the substrate 100, an etching target film (not shown) may be further formed on the substrate 100. The etching target film may refer to a layer on which an image is transferred from a resist pattern and converted into a certain pattern. In an embodiment, the etching target film may be formed to include, for example, an insulating material such as silicon oxide, silicon nitride, or silicon oxynitride. In some embodiments, the etching target film may be formed to include a conductive material such as a metal, metal nitride, metal silicide, or metal silicide nitride. In some embodiments, the etching target film may be formed to include a semiconductor material such as polysilicon.

In an embodiment, an antireflection film may be further formed on the substrate 100 to maximize the efficiency of a resist. The antireflection film may be an organic or inorganic antireflection film.

In an embodiment, a protective film may be further provided on the resist film 110 to reduce the influence of alkaline impurities or the like included during a process. When immersion exposure is performed, for example, a protective film for immersion may also be provided on the resist film 100 to avoid direct contact between an immersion medium and the resist film 110.

Next, at least a portion of the resist film 110 may be exposed to high energy rays. For example, high energy rays passing through a mask 120 may be irradiated onto at least a portion of the resist film 110. For this reason, the resist film 110 may have an exposed portion 111 and an unexposed portion 112.

Although not limited to a specific theory, radicals are generated in the exposed portion 111 by exposure, and chemical bonds are formed between the radicals, which may change the physical properties of the resist composition.

In some cases, the exposure may be performed by irradiating high energy rays through a mask with a certain pattern using a liquid such as water as a medium. Examples of the high-energy rays may include electromagnetic waves such as ultraviolet rays, deep ultraviolet rays, extreme ultraviolet (EUV) rays (wavelength of 13.5 nm), X-rays, and γ-rays; and charged particle beams such as electron beams (EBs) and α particle beams. Irradiating the high energy rays may be collectively referred to as “exposure.”

Various light sources may be used for the exposure. For example, a light source emitting laser beams in the UV range, such as a KrF excimer laser (wavelength of 248 nm), an ArF excimer laser (wavelength of 193 nm), and an F₂ excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting EB or EUVs may be used. During exposure, the exposure may be usually performed through a mask corresponding to a desired pattern, but when exposure light is an EB, the exposure may be performed through direct writing without using a mask.

In the case of using extreme ultraviolet rays as the high-energy rays, an integral dose of the high-energy rays may be 2000 mJ/cm² or less or 500 mJ/cm² or less. In addition, when EB are used as the high energy rays, the integral dose may be 5,000 μC/cm² or less, or 1,000 μC/cm² or less.

In addition, post-exposure bake (PEB) may be performed after the exposure. The lower limit of the temperature of PEB may be 50° C. or more or 80° C. or more. An upper limit of the PEB temperature may be 250° C. or lower, or 200° C. or lower. The lower limit of the time of the PEB time may be 5 seconds or more or 10 seconds or more. The upper limit of the time of the PEB may be 600 seconds or less or 300 seconds or less.

Next, the exposed resist film 110 may be developed using a developer. The non-exposed region 112 may be removed by being washed away by the developer, and the exposed portion 111 remains without being washed away by the developer.

Examples of the developer are an alkaline developer and a developer including an organic solvent (hereinafter also referred to as “organic developer”). Examples of a developing method are a dipping method, a puddle method, a spray method, a dynamic injection method, and the like. A developing temperature may be, for example, 5° C. or more and 60° C. or less, and a developing time may be, for example, 5 seconds or more and 300 seconds or less.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, TMAH, pyrrole, piperidine, choline, 1,8-diazabicyclo[5.4.0]-7-undecene (DBU), and 1,5-diazabicyclo[4.3.0]-5-nonene (DBN) are dissolved. The alkali developer may further include a surfactant.

A lower limit of an amount of the alkaline compound contained in the alkaline developer may be 0.1 wt % or more or 0.5 wt % or more, or 1 wt % or more. In an embodiment, an upper limit of the amount of the alkaline compound contained in the alkaline developer may be 20 wt % or less, or 10 wt % or less, or 5 wt % or less.

Examples of the organic solvent included in the organic developer may include the same organic solvents as those exemplified in the part of <Organic solvent> of [Resist composition]. In an embodiment, the organic developer may be n-butyl acetate (nBA), propylene glycol methyl ether (PGME), propylene glycol methyl ether acetate (PGMEA), γ-butyrolactone (GBL), isopropanol (IPA), etc. The organic developer may include more organic acids such as acetic acid, formic acid, citric acid, etc.

Regarding the organic developer, a lower limit of the amount of the organic solvent may be 80 wt % or more, 90 wt % or more, 95 wt % or more, or 99 wt % or more.

The organic developer may also include a surfactant. In addition, a trace amount of water may be included in the organic developer. In some embodiments, during development, development may be stopped by substituting with a different kind of solvent from the organic developer.

The resist pattern after the development may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and the resist pattern may be removed. In addition, when the ultrapure water is used, water remaining on the substrate 100 and the resist pattern may be removed.

In addition, developers may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. One or more embodiments are not limited thereto, but examples of such an organic solvent may include PGMEA, PGME, ethyl lactate (EL), and the like. A peeling method is not particularly limited, but examples thereof may include an immersion method, a spray method, and the like. In addition, the interconnection substrate on which the resist pattern is formed may be a multilayer interconnection substrate or may have small-diameter through-holes.

In an embodiment, the interconnection substrate may be formed through a method of forming a resist pattern, depositing a metal in a vacuum, and then melting the resist pattern with a solution, that is, a lift-off method.

The disclosure will be described in more detail using the following examples and comparative Examples, but the technical scope of the disclosure is not limited only to the following non-limiting examples.

### Examples

### Synthesis Example 1: Synthesis of SM1

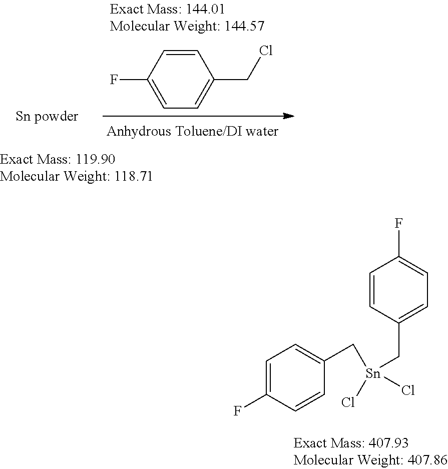 [SMILES: Fc1ccc(CCl)cc1 ; Fc1ccc([CH2][Sn]([Cl])([Cl])[CH2]c2ccc(F)cc2)cc1]

8.2 g (69.2 mmol) of Sn powder and 120 ml of dry toluene were added to a 250 ml three-necked flask, and the temperature was raised to 90° C. About 1.0 ml of DI water was added thereto, and then, 10.0 g (69.2 mmol) of 4-fluorobenzyl chloride was added dropwise for 10 minutes. Heating, refluxing and stirring were performed at 130° C. for 4 hours, and then, unreacted Sn powder was filtered out using a Buchner funnel. At the same time, as the filtered solution was cooled, 6.5 g of white crystals (SM1 precursor) were obtained as a product (yield of 36%).

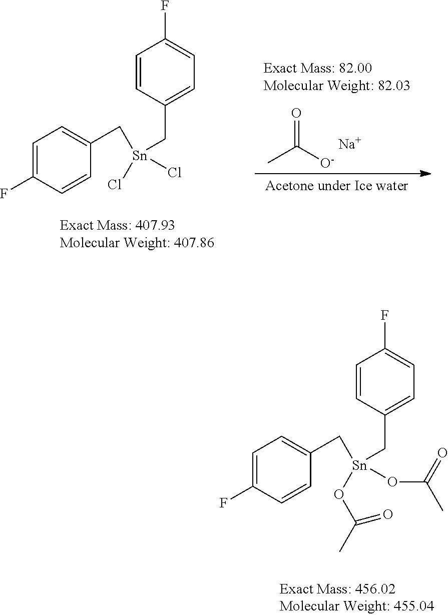

1.5 g (3.7 mmol) of SM1 precursor and 21.0 ml of dry acetone were added to a 50 ml single-necked flask, and the temperature was lowered to 0° C. 0.6 g (7.4 mmol) of sodium acetate was added thereto, and then, stirred for about 12 hours. NaCl salt produced in the solution was filtered using a 0.45 μm filter, and the resultant solution was concentrated by rotary evaporation and dried under vacuum to obtain SM1 (1.6 g) with the yield of 74%.

¹H-NMR (500 MHz, DMSO-d₆): δ˜6.9 (8H), ˜2.6 (4H), ˜1.6 (6H)

### Preparation Example: Preparation of Casting Solution

The organometallic compound synthesized in Synthesis Example 1 was dissolved in ethyl lactate at 2 wt %, and then 0.5 equivalents (based on the amount of organometallic compound as 1 equivalent) of the additive shown in Table 1 below was added to prepare Casting Solution A-1 to Casting Solution A-4.

Casting Solution A-1 to Casting Solution A-4 were stored in an oven at 40° C. for 12 days to obtain Casting Solution B-1 to Casting Solution B-4.

TABLE 1

| Casting | Organometallic | | Casting | Post- |
|---|---|---|---|---|
| Solution No. | compound | Additive | solvent | treatment |
| A-1 | SM1 | — | Ethyl lactate | None |
| A-2 | SM1 | Compound A | Ethyl lactate | None |
| A-3 | SM1 | Compound B | Ethyl lactate | None |
| A-4 | SM1 | Compound C | Ethyl lactate | None |
| B-1 | SM1 | — | Ethyl lactate | Performed |
| B-2 | SM1 | Compound A | Ethyl lactate | Performed |
| B-3 | SM1 | Compound B | Ethyl lactate | Performed |
| B-4 | SM1 | Compound C | Ethyl lactate | Performed |

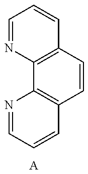

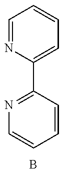

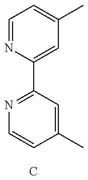

The post-treatment in Table 1 refers to the storage in an oven at 40° C. for 12 days.

### Evaluation Example 1: Storage Stability Evaluation

### (1) Visual Evaluation

For Casting Solutions B-1 to B-4, changes over time were determined with the naked eye. Casting Solution B-2 to B-4 containing additives showed no change over time, and Casting Solution B-1 without an additive showed visible changes.

### (2) Surface Roughness (Rq) Evaluation

An 8-inch diameter silicon wafer was cut into quarters, treated with O₂ plasma for 30 minutes, spin-coated with Casting Solution A-1 to Casting Solution A-4 and Casting Solution B-1 to Casting Solution B-4 at 1500 rpm for 1 minute each, and then dried (PAB) for 1 minute to 120° C., thereby producing a film having the initial thickness shown in Table 2. Then, a 3.5 mm thick zig (4×4) with rectangular holes (1 cm×1 cm) was placed on the films obtained using Casting Solution B-1 to Casting Solution B-4, and each hole was exposed to deep ultraviolet (DUV) rays at a wavelength of 254 nm with a dose of 0 mJ/cm² to 100 mJ/cm², and the resultant structure was dried (PEB) at 200° C. for 1 minute. The dried films were soaked at 25° C. for 60 seconds using a PGMEA solution containing 2 wt % acetic acid as a developer, and then the surface of the remaining film was identified through an atomic force microscope, and Rq was calculated from the average value of the observed height, and the results are listed in Table 2 below.

TABLE 2

| | | Initial thickness | |
|---|---|---|---|
| | Casting Solution No. | (nm) | Rq (nm) |
| Comparative | A-1 | 23.69 | — |
| Example 1-1 | | | |
| Example 1-1 | A-2 | 25 | — |
| Example 1-2 | A-3 | 22 | — |
| Example 1-3 | A-4 | 20.52 | — |
| Comparative | B-1 | 8.23 | 0.385 |
| Example 2-1 | | | |
| Example 2-1 | B-2 | 23.53 | 0.314 |
| Example 2-2 | B-3 | 20.29 | 0.297 |
| Example 2-3 | B-4 | 22.64 | 0.317 |

Referring to Table 2, in the case of Comparative Example 2-1 without an additive, the thickness of a thin film formed after storage at high temperature was significantly reduced compared to before storage, confirming that storage stability is low, and in the case of Examples 2-1 to 2-3 in which an additive was added, a similar level of thin film thickness as before storage could be secured even after high-temperature storage, confirming that storage stability is relatively high.

Additionally, in the case of Examples 2-1 to 2-3 in which an additive is added, Rq is smaller than that of Comparative Example 2-1. As a result, it was confirmed that the coating characteristics of a resist composition to which an additive is added are improved.

### Evaluation Example 2: Evaluation of Thin Film Development

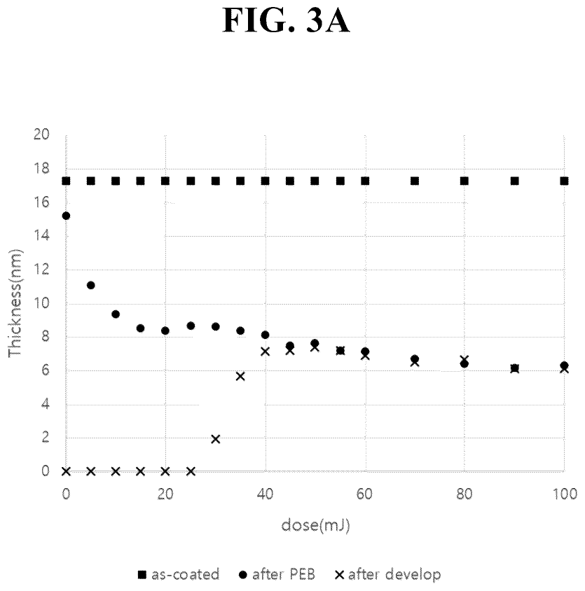

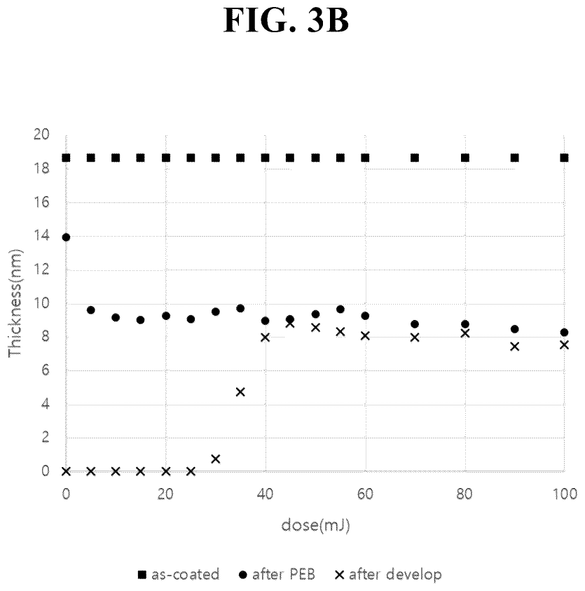

2 wt % SM1 obtained in Synthesis Example 1 was dissolved in ethyl lactate and 0.2 equivalents of 1,10-phenanthroline was further added thereto as an additive (SM1: 1,10-phenanthroline=12:1 (mass ratio)) to obtain Casting Solution C-1. Meanwhile, Casting Solution C-2 having the same composition as Casting Solution C-1 was obtained, except that 1,10-phenanthroline was not added. A silicon wafer with a diameter of 4 inches was treated with O₂ plasma for 30 minutes, spin-coated with Casting Solution C-1 and Casting Solution C-2 at 1200 rpm for 1 minute each, and then dried (PAB) at 90° C. for 1 minute to produce a film with the initial thickness shown in Table 3 below. Then, a 3.5 mm thick zig (4×4) with rectangular holes (1 cm×1 cm) was placed thereon, and each hole was exposed to DUV rays at a wavelength of 254 nm with a dose of 0 mJ/cm² to 100 mJ/cm², and the resultant structure was dried (PEB) at 200° C. for 1 minute. The dried film was soaked in a PGMEA solution containing 2 wt % acetic acid as a developer, at 25° C. for 60 seconds. The thickness of the remaining film was measured and shown in Table 3 and FIGS. 3A and 3B. Regarding FIGS. 3A and 3B, the term “as-coated” indicates reference data for a sample after PAB, the term “after PEB” indicates reference data for a sample after PEB but before treatment with the developer, and the term “after develop” indicates reference data for a sample which has been treated with a developer.

TABLE 3

| | | | | Initial | | | |
|---|---|---|---|---|---|---|---|
| | Casting | Organometallic | | thickness | Eₜₕ | E₁ | |
| | Solution | compound | Additive | (nm) | (mJ) | (mJ) | Graph |
| Comparative | C-1 | SM1 | — | 17 | 30 | 40 | FIG. |
| Example | | | | | | | 3A |
| 3-1 | | | | | | | |
| Example 3-1 | C-2 | SM1 | 1,10- | 19 | 30 | 40 | FIG. |
| | | | phenanthroline | | | | 3B |

In Table 3, Eₜₕ refers to the exposure amount at the point when a thin film begins to harden, and E₁ refers to the exposure amount at the saturation point where the thickness of a thin film no longer increases.

Referring to Table 3, it can be seen that Eₜₕ and E₁ of Example 3-1 are at levels similar to Eₜₕ and E₁ of Comparative Example 3-1. From this result, it can be confirmed that even when an additive is used, there is no decrease in photosensitivity.

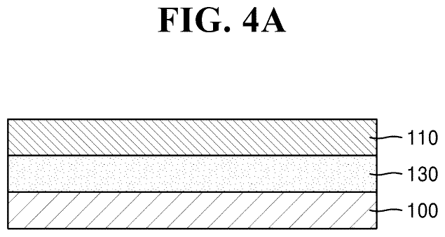

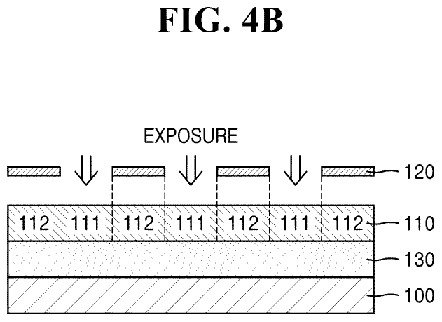

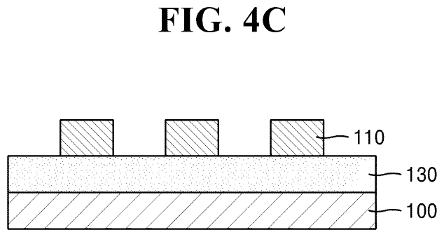

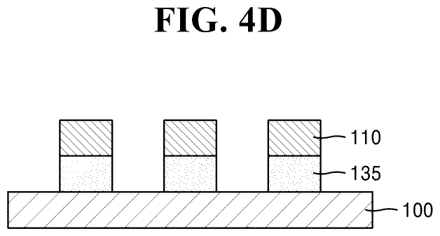

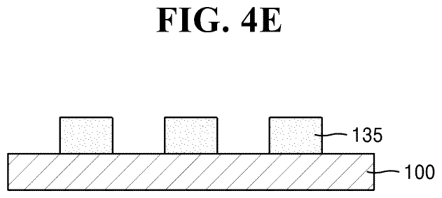

FIGS. 4A to 4E are side cross-sectional views illustrating a method of forming a patterned structure according to an embodiment.

Referring to FIG. 4A, a material layer 130 may be formed on the substrate 100 before forming a resist film 110 on the substrate 100. The resist film 110 may be formed on top of the material layer 130. The material layer 130 may include an insulating material (e.g., silicon oxide, silicon nitride), a semiconductor material (e.g., silicon), a metal (e.g., copper). In some embodiments, the material layer 130 may be a multi-layer structure. A material of the material layer 130 may be different than a material of the substrate 100. The resist film 110 may include a resist composition according to example embodiments and may have a thickness of about 10 nm to about 300 nm or about 30 nm to about 200 nm.

Referring to FIG. 4B, the resist film 110 may be exposed with high energy rays through a mask 120, after which the resist film 110 may include an exposed portion 111 and an unexposed portion 112.

Referring to FIG. 4C, to form a resist pattern 110, the exposed resist film 110 may be developed using a developer (e.g., developing solution). The exposed portion 111 may remain without being washed away by the developer, whereas the non-exposed portion 112 may be washed away by the developer.

Referring to FIG. 4D, exposed areas of the material layer 130 may be etched using the resist pattern 110 as a mask to form a material pattern 135 on the substrate 100.

Referring to FIG. 4E, the resist pattern 110 may be removed.

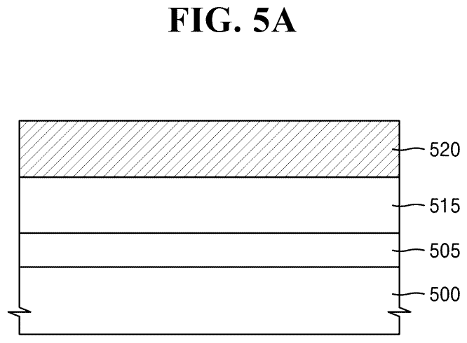

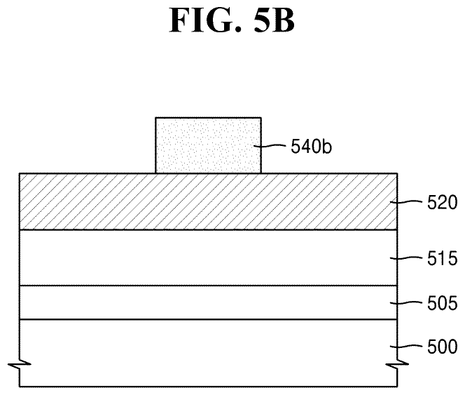

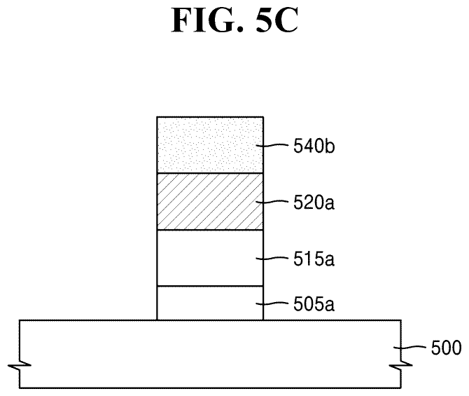

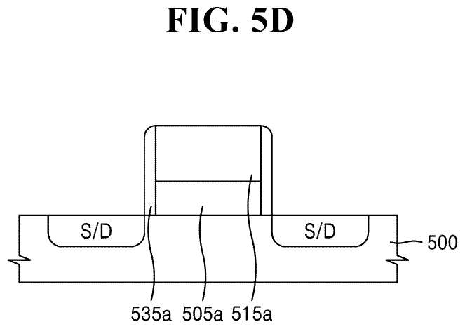

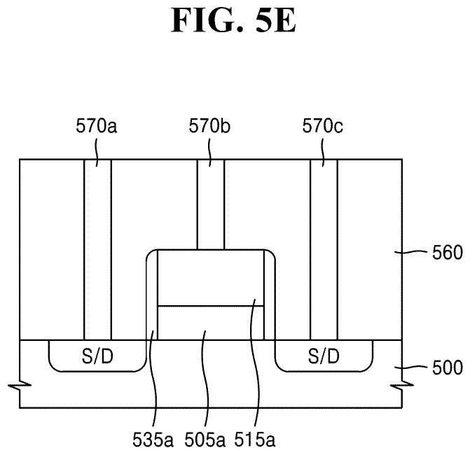

FIGS. 5A to 5E are side cross-sectional views illustrating a method of forming a semiconductor device according to an embodiment.

Referring to FIG. 5A, a gate dielectric 505 (e.g., silicon oxide) may be formed on a substrate 500. The substrate 500 may be a semiconductor substrate, such as a silicon substrate. A gate layer 515 (e.g., doped polysilicon) may be formed on the gate dielectric 505. A hardmask layer 520 may be formed on the gate layer 515.

Referring to FIG. 5B, a resist pattern 540b may be formed on the hardmask layer 520. The resist pattern 540b may be formed using a resist composition according to example embodiments. The resist pattern 540b may be formed from a resist composition according to an example embodiment.

Referring to FIG. 5C, the gate layer 515 and the gate dielectric 505 may be etched to form a hardmask pattern 520a, a gate electrode pattern 515a, and a gate dielectric pattern 505a.

Referring to FIG. 5D, the hardmask pattern 520a optionally may be removed and a spacer layer may be formed over the gate electrode pattern 515a and the gate dielectric pattern 505a. The spacer layer may be formed using a deposition process (e.g., CVD). The spacer layer may be etched to form spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

Referring to FIG. 5E, an interlayer insulating layer 560 (e.g., oxide) may be formed on the substrate 500 to cover the gate electrode pattern 515a, gate dielectric pattern 505a, and spacers 535a. Then, electrical contacts 570a, 570b, and 570c may be formed in the interlayer insulating layer 560 to connect to the gate electrode 515a and the S/D regions. The electrical contacts may be formed of a conductive material (e.g., metal). Although not illustrated, a barrier layer may be formed between sidewalls of the interlayer insulating layer 560 and the electrical contacts 570a, 570b, and 570c. While FIGS. 5A to 5E illustrate an example of forming a transistor, inventive concepts are not limited thereto.

A resist composition according to one or more embodiments may be used in a patterning process to form other types of semiconductor devices.

According to the embodiments, a resist composition having improved storage stability and improved sensitivity and providing a pattern with increased resolution may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
an organometallic compound represented by one of Formulae 1-1 to 1-4; and
an additive represented by Formula 2, 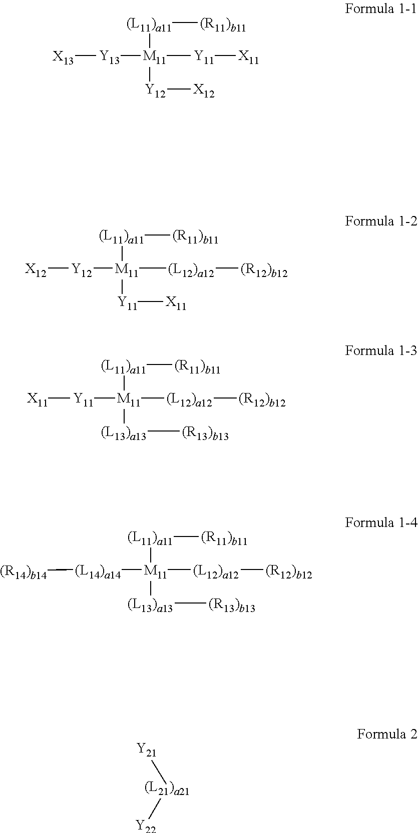
wherein, in Formulae 1-1 to 1-4 and 2,
M₁₁ is indium (In), tin (Sn), antimony (Sb), tellurium (Te), thallium (Tl), lead (Pb), bismuth (Bi), or polonium (Po),
L₁₁ to L₁₄ are each independently a single bond or a linear, branched, or cyclic C₁-C₃₀ divalent hydrocarbon group,
a11 to a14 are each independently an integer from 1 to 4, and
R₁₁ to R₁₄ are each independently a substituted or unsubstituted C₃-C₃₀ branched alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
an adjacent two of R₁₁ to R₁₄ are optionally combined with each other to form a condensed ring,
b11 to b14 are each independently an integer from 1 to 4,
Y₁₁ to Y₁₃ are each independently O, O(C═O), S, S(C═O), NX₁₄, or N(C═O),
X₁₁ to X₁₄ are each independently hydrogen, deuterium, or a linear, branched, or cyclic C₁-C₃₀ monovalent hydrocarbon group optionally including a heteroatom,
Y₂₁ and Y₂₂ are each independently a linear, branched, or cyclic C₁-C₃₀ monovalent hydrocarbon group containing, as a heteroatom, at least one selected from an oxygen atom, a sulfur atom, a nitrogen atom and a phosphorus atom,
L₂₁ is a single bond, a double bond, or a linear, branched, or cyclic C₁-C₃₀ divalent hydrocarbon group,
a21 is an integer from 1 to 4, and
an adjacent two of Y₂₁, Y₂₂, and L₂₁ are optionally combined with each other to form a condensed ring.

2. The resist composition of claim 1, wherein
M₁₁ is In, Sn, or Sb.

3. The resist composition of claim 1, wherein
L₁₁ to L₁₄ are each independently a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

4. The resist composition of claim 1, wherein
R₁₁ to R₁₄ are each independently selected from a branched C₃-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

5. The resist composition of claim 1, wherein
the organometallic compound is represented by one of Formulae 1-1 to 1-3,
Y₁₁ to Y₁₃ are each independently O, O(C═O), S, or S(C═O).

6. The resist composition of claim 1, wherein
X₁₁ to X₁₄ are each independently selected from: hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

7. The resist composition of claim 1, wherein
the organometallic compound represented by one of Formulae 1-1 to 1-4 is selected from Group I: 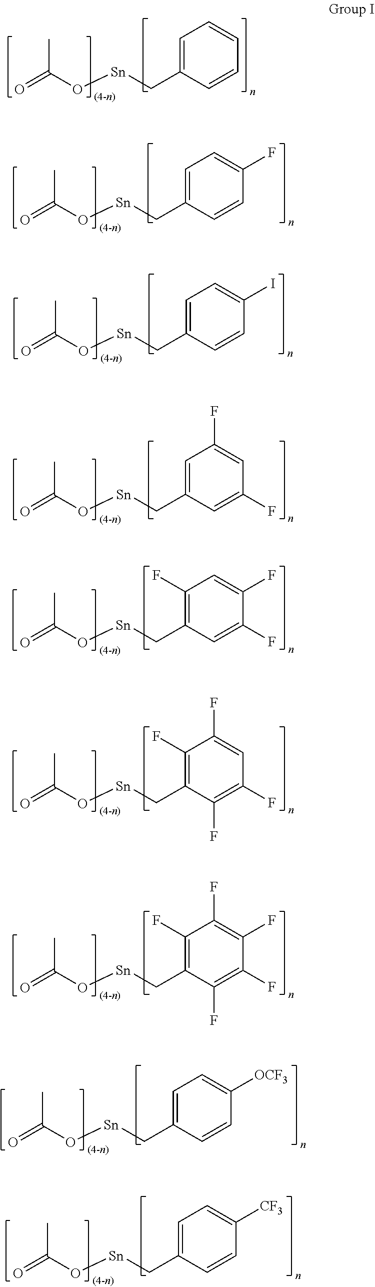 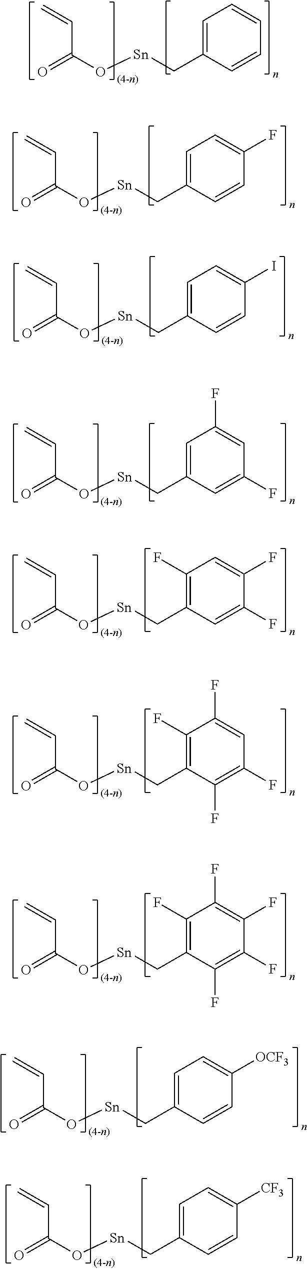 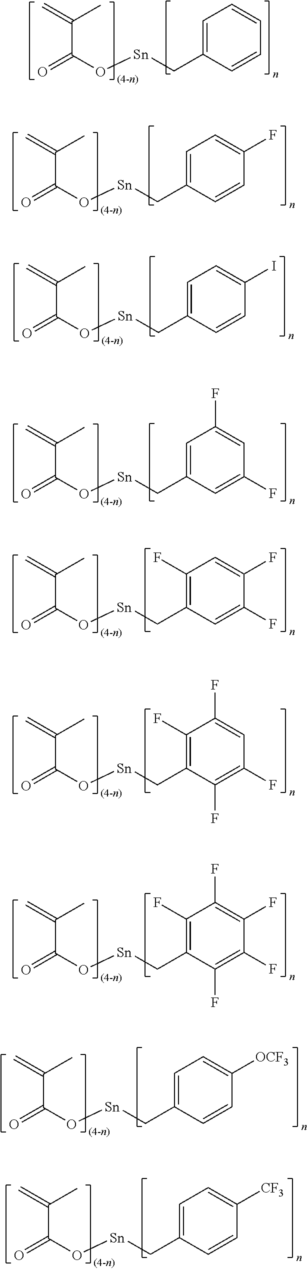
wherein n in Group I is an integer from 1 to 4.

8. The resist composition of claim 1, wherein
Y₂₁ is represented by one of Formulae 4-1 to 4-5, and
Y₂₂ is represented by one of Formulae 4-6 to 4-10: 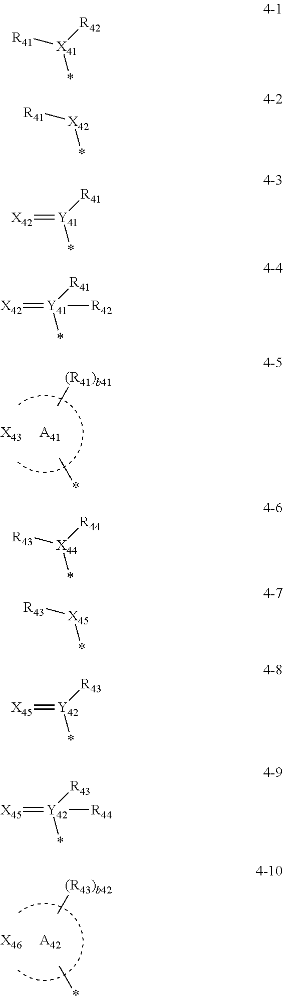
wherein, in Formulae 4-1 to 4-10,
X₄₁ and X₄₄ are each independently N or P,
X₄₂ and X₄₅ are each independently O or S,
X₄₃ and X₄₆ are each independently O, S, N, or P,
Y₄₁ and Y₄₂ are each independently C, S, or P,
A₄₁ is a C₁-C₃₀ heterocyclic group including X₄₃ as a ring member,
A₄₂ is a C₁-C₃₀ heterocyclic group including X₄₆ as a ring member,
R₄₁ to R₄₄ are each independently hydrogen, deuterium, a halogen atom, a cyano group, a nitro group, a hydroxy group, a thiol group, an amino group, a carboxylate group, or a linear, branched, or cyclic C₁-C₃₀ divalent hydrocarbon group,
b41 and b42 are each independently an integer from 1 to 10, and
* indicates a binding site to a neighboring atom.

9. The resist composition of claim 8, wherein
A₄₁ and A₄₂ are each i) independently a monovalent group derived from a first ring, ii) a monovalent group derived from a condensed ring in which two or more first rings are condensed with each other, or iii) a monovalent group derived from a condensed ring in which one or more first rings are condensed with one or more second rings,
the first ring is tetrahydropyran, dihydropyran, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine, or triazine, and
the second ring is cyclopentane, cyclopentadiene, cyclohexane, cyclohexene, cyclohexadiene, benzene, or naphthalene.

10. The resist composition of claim 8, wherein
Y₂₁ is represented by Formula 4-5, and Y₂₂ is represented by one of Formulae 4-6 to 4-10, or
Y₂₁ is represented by one of Formulae 4-1 to 4-5, and Y₂₂ is represented by Formula 4-10.

11. The resist composition of claim 1, wherein
L₂₁ is a single bond, a double bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

12. The resist composition of claim 1, wherein
the additive is represented by Formula 2-1: 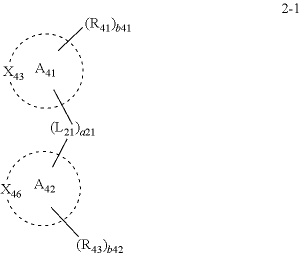
wherein, in Formula 2-1,
X₄₃ and X₄₆ are each independently O, S, N, or P,
A₄₁ is a C₁-C₃₀ heterocyclic group including X₄₃ as a ring member,
A₄₂ is a C₁-C₃₀ heterocyclic group including X₄₆ as a ring member,
L₂₁ is a single bond, a double bond, or a linear, branched, or cyclic C₁-C₃₀ divalent hydrocarbon group,
a21 is an integer from 1 to 4,
R₄₁ to R₄₄ are each independently a linear, branched, or cyclic C₁-C₃₀ divalent hydrocarbon group,
b41 and b42 are each independently an integer from 1 to 10, and
an adjacent two of R₄₁, R₄₃, and L₂₁ are optionally combined with each other to form a condensed ring.

13. The resist composition of claim 1, wherein
the additive is selected from Group II:

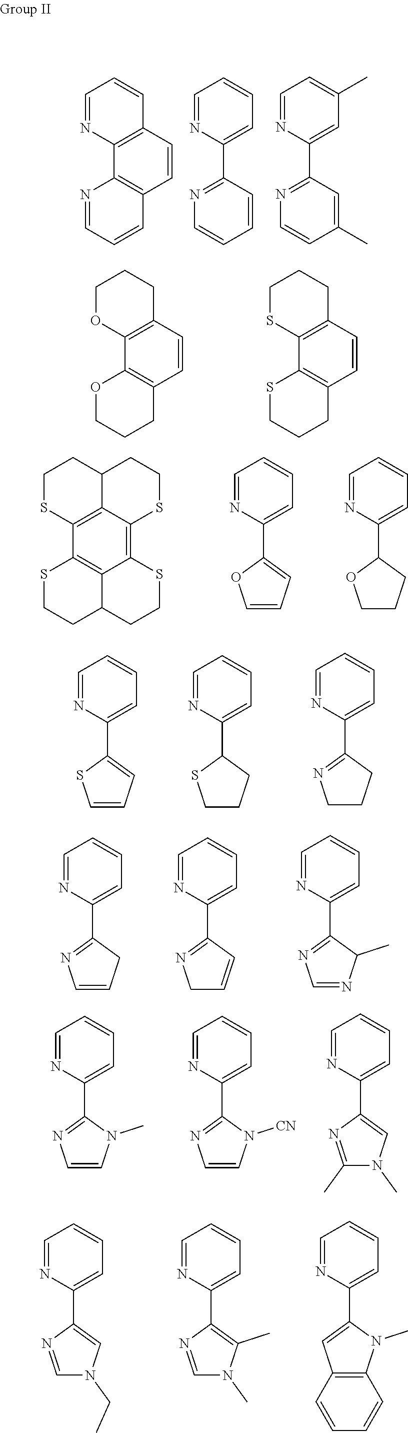

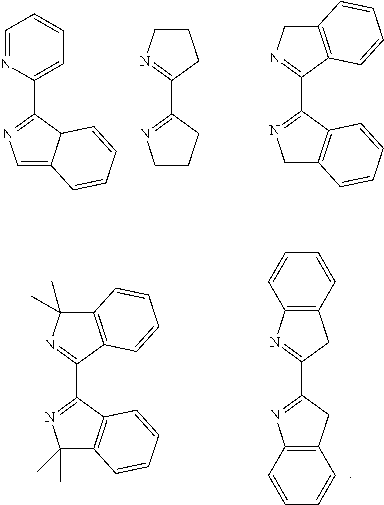

14. The resist composition of claim 1, wherein
the additive is included in an amount of about 0.1 parts by weight to about 100,000 parts by weight based on 100 parts by weight of the organometallic compound.

15. The resist composition of claim 1, wherein
the resist composition does not include a photoacid generator.

16. The resist composition of claim 1, wherein
the resist composition substantially does not include a compound having a molecular weight of 1,000 or more.

17. A pattern formation method comprising:
forming a resist film by applying the resist composition of claim 1 on a substrate;
exposing at least a portion of the resist film to high energy rays to provide an exposed resist film; and
developing the exposed resist film using a developer.

18. The pattern formation method of claim 17, wherein
the exposing at least a portion of the resist film is performed by at least one of irradiating deep ultraviolet (DUV) rays, extreme ultraviolet (EUV) rays, or electron beams (EBs).

19. The pattern formation method of claim 17, wherein
the organometallic compound is subjected to a condensation reaction during the exposing at least the portion of the resist film.

20. The pattern formation method of claim 17, wherein
the exposed resist film includes an exposed portion and a non-exposed portion, and
in the developing, the non-exposed portion is removed.
